(19) United States
(12) Patent Application Publication
(10) Pub. No.: US 2016/0124322 A1
(43) Pub. Date: May 5, 2016

(54) LITHOGRAPHY APPARATUS, LITHOGRAPHY METHOD, AND ARTICLE MANUFACTURING METHOD

(71) Applicant: CANON KABUSHIKI KAISHA, Tokyo (JP)

(72) Inventors: Satoru Oishi, Utsunomiya-shi (JP); Hideki Ina, Tokyo (JP)

(21) Appl. No.: 14/922,575

(22) Filed: Oct. 26, 2015

(30) Foreign Application Priority Data
Oct. 30, 2014 (JP) 2014-222045

(51) Int. Cl. G03F 7/20; G03F 9/00

(52) U.S. Cl. CPC G03F 7/70633; G03F 9/708

(57) ABSTRACT

At least one lithography apparatus, lithography method and method of manufacturing an article are provided herein. At least one lithography apparatus for performing patterning on a substrate, includes a stage configured to hold the substrate and be movable, an irradiation device configured to irradiate the substrate with a beam for the patterning, and a controller configured to cause the stage and the irradiation device to perform a first process of forming, on a substrate including a zeroth mark for overlay inspection, a first mark for overlay inspection to be paired with the zeroth mark and a second mark for overlay inspection, with the patterning not being performed, and to perform a second process of forming, on the substrate, a third mark for overlay inspection to be paired with the second mark, with the patterning being performed.

### BACKGROUND OF THE INVENTION

1. Field of the Invention

The present disclosure relates to a lithography apparatus for performing patterning on a substrate, a lithography method, and an article manufacturing method.

2. Description of the Related Art

Candidates for future lithography processes (for example, lithography processes for manufacturing a semiconductor device having a half pitch of 16 nm or less) include multiple electron beam lithography. In the multiple electron beam lithography, there is a concern that a large amount of power (energy) is incident on a substrate (such as a wafer). More specifically, the multiple electron beam lithography may have the difficulty in achieving required overlay accuracy because of thermal deformation of the wafer due to the large amount of power. This concern may arise also in other lithography processes such as liquid immersion (ArF) lithography and extreme ultraviolet (EUV) light lithography.

A technique discussed in Japanese Patent Application Laid-Open No. 2004-128196 is known as a measure for such thermal deformation. The technique discussed in Japanese Patent Application Laid-Open No. 2004-128196 calculates and stores data required to correct the amount of deviation appearing at the irradiation position of an electron beam based on a result of calculation of thermal deformation appearing on a sample irradiated with the electron beam, and then corrects at least either one of the irradiation quantity and the irradiation position of the electron beam according to the relevant data.

A substrate processing apparatus discussed in U.S. Pat. No. 7,897,942 measures positions of a plurality of targets (marks) formed on a substrate during movement and processing (drawing). Then, the apparatus performs curve fitting processing on the shape of the substrate between a plurality of targets to compensate deformation of the substrate during processing.

An electron beam exposure method discussed in Japanese Patent Publication No. 05-044172 first exposes a plurality of positions within an exposure surface of a base material (substrate) to a part of marks for detecting pattern exposure deviations due to resist charge-up. Then, while exposing the substrate to a base material pattern, the method sequentially exposes respective positions to the other part of marks in an overlapped manner. With this method, by detecting the exposure deviation detection marks, the exposure deviations due to resist charge-up can be detected.

An overlay error is caused by various factors such as a thermal distortion of a substrate, a magnetic field change, a resist charge, and characteristics of a lithography apparatus. As illustrated in FIG. 14, overlay inspection marks OL are arranged at several portions (4 portions are illustrated in FIG. 14) in scribing area (scribing region) 34 around an area 33 corresponding to a manufacturing target element (article). Therefore, as illustrated by arrows illustrated in FIG. 14, the distance between marks OL is about 10 to 20 mm. On the other hand, in the case of multiple electron beam lithography, for example, the size of the drawing field (for example, 50 μm or around x several micrometers) is remarkably small as compared with the relevant distance. Therefore, there may be a case where only measuring such marks OL is not sufficient for compensating overlay errors.

### SUMMARY OF THE INVENTION

The present disclosure is directed to, for example, a lithography apparatus that is advantageous in terms of overlay performance thereof.

According to an aspect of the present disclosure, a lithography apparatus for performing patterning on a substrate, includes a stage configured to hold the substrate and be movable, an irradiation device configured to irradiate the substrate with a beam for the patterning, and a controller configured to cause the stage and the irradiation device to perform a first process of forming, on a substrate including a zeroth mark for overlay inspection, a first mark for overlay inspection to be paired with the zeroth mark and a second mark for overlay inspection, with the patterning not being performed, and to perform a second process of forming, on the substrate, a third mark for overlay inspection to be paired with the second mark, with the patterning being performed.

According to other aspects of the present disclosure, one or more additional lithography apparatuses, one or more lithography methods, and one or more article manufacturing methods are discussed herein. Further features of the present disclosure will become apparent from the following description of exemplary embodiments with reference to the attached drawings.

### BRIEF DESCRIPTION OF THE DRAWINGS

FIG. 1 illustrates an example of a configuration of a lithography apparatus.

FIG. 2 illustrates an example of a patterning strategy in the lithography apparatus.

FIG. 3 is a flowchart illustrating common processing for a first to a third exemplary embodiment.

FIG. 4 is a flowchart illustrating processing in step S120 illustrated in FIG. 3.

FIG. 5 illustrates an algorithm for acquiring overlay errors (correction amounts).

FIG. 6 illustrates an example of a configuration of overlay inspection marks.

FIGS. 7A, 7B, and 7C illustrate examples of configurations of overlay inspection marks.

FIG. 8 illustrates an example of an arrangement of overlay inspection marks.

FIG. 9 illustrates an algorithm for acquiring overlay errors according to the second exemplary embodiment.

FIG. 10 is a flowchart illustrating processing in step S120 illustrated in FIG. 3 according to the second exemplary embodiment.

FIG. 11 supplements descriptions of FIG. 9.

FIG. 12 illustrates an algorithm for acquiring overlay errors according to the third exemplary embodiment.

FIG. 13 is a flowchart illustrating processing in step S120 illustrated in FIG. 3 according to the third exemplary embodiment.

FIG. 14 illustrates a problem to be solved by the present disclosure.

### DESCRIPTION OF THE EMBODIMENTS

Exemplary embodiments of the present disclosure will be described below with reference to the accompanying drawings. Through all of the drawings for illustrating exemplary embodiments, as a rule (unless otherwise specifically described), identical elements are assigned the same reference numeral and duplicated descriptions will be omitted.

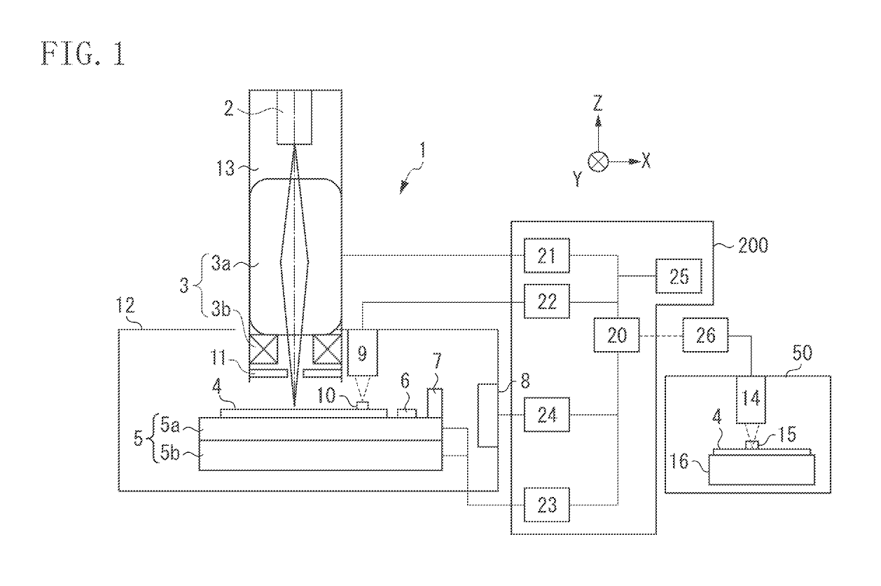

FIG. 1 illustrates an example of a configuration of a lithography apparatus 1 according to a first exemplary embodiment. As an example of the lithography apparatus 1, an electron beam lithography apparatus (generally referred to as a charged-particle beam lithography apparatus) will be described below with reference to FIG. 1. However, the lithography apparatus is not limited thereto. The lithography apparatus may perform patterning (i.e., forming (formation) of a pattern related to an article) on a substrate by using an energy ray (beam) such as a focused ion beam, a laser beam, ArF light, and EUV light.

### [Example Configuration of Lithography Apparatus]

Referring to FIG. 1, an electron optical system (charged-particle optical system) 13 (also referred to as an optical system, a column, or an irradiation unit) includes at least an electron optical system element 3 for irradiating a substrate 4 with an electron beam emitted from an electron gun 2 (the electron optical system 13 may includes an electron gun or a radiation source). The electron gun 2 may be shared by a plurality of the electron optical systems 13. The electron optical system element 3 can include an electron lens system 3a (including a blanker) for focusing an electron beam, and a deflector 3b for deflecting the electron beam. An optical system control unit 21 can control the electron beam focusing position (focusing), the deflection amount (irradiation position), and blanking via (by controlling) the electron optical system 13. A blanking unit (blanker array) (not illustrated) for performing blanking can include an array of electrode pairs which can be individually driven, and an opening array member for allowing passage of an electron beam that was not deflected by the relevant electrode pairs and blocking an electron beam deflected by the relevant electrode pairs.

A movable stage 5 holding the substrate 4 can be composed of a Y stage 5b, an X stage 5a mounted on the Y stage 5b, and a Z stage (not illustrated). The substrate 4 is held by a (substrate) chuck (not illustrated) included in the stage 5. A stage control unit 23 controls the movement of the X stage 5a in an X-axis direction, the movement of the Y stage 5b in a Y-axis direction, and the movement of the Z stage in a Z-axis direction. A reference member 6 with reference marks formed thereon and a moving mirror 7 for the X axis are provided on the stage 5. The reference marks can be used to measure the positional difference (also referred to as a baseline) between the optical axis of a mark detection unit 9 (described below) and the optical axis of the electron optical system 13.

An interferometer 8 splits light (for example, a laser beam) into measurement light and reference light, inputs the measurement light to the moving mirror 7, and inputs the reference light to a reference mirror (not illustrated) provided inside the interferometer 8. The interferometer 8 interferes between the light reflected by the two relevant mirrors to detect the intensity of the resultant interference light. Based on that detection, an interferometer control unit 24 acquires (measures) the position of the moving mirror 7 with reference to the reference mirror, i.e., the position of the stage 5 in the X-axis direction (X coordinates). In a similar way, the interferometer control unit 24 can measure the position of the stage 5 in the Y-axis direction (Y coordinates) by using a moving mirror for the Y-axes (not illustrated) provided on the X stage 5a. The interferometer control unit 24 transmits measurement values to a main control unit 20. Based on the measurement values, the main control unit 20 can control the position of the stage 5 via the stage control unit 23.

Resist is applied to the substrate 4. The mark detection unit 9 irradiates the reference member 6 and the substrate 4 with light having a wavelength to which resist is not photosensitive, and captures images of reference marks on the reference member 6 and alignment marks 10 formed on the substrate 4. The mark detection unit control unit 22 processes outputs (image signals for marks) of the mark detection unit 9 to acquire (measure) the positions of the reference marks and the alignment marks 10. The mark detection unit 9 may temporally detect diffracted light from portions of moving marks. In this case, the mark detection unit control unit 22 may acquire mark positions based on changes of outputs of the mark detection unit 9.

A focus detection unit 11 detects physical quantities having a correlation with surface positions of the substrate 4 in the Z-axis direction. Since electron beam lithography performs patterning (drawing) under a vacuum environment, the focus detection unit 11 can include a sensor suitable for use in a vacuum, such as an optical sensor and a capacitance sensor. The focus detection unit 11 including an optical sensor can emit oblique incidence light onto the surface of the substrate 4, and capture a light spot formed on the surface of the substrate 4 by the oblique incidence light, by using an image sensor disposed at a position optically conjugate with the relevant surface of the substrate 4. A focus detection unit control unit (not illustrated) acquires (measures) the position of the surface of the substrate 4 in the Z-axis direction, based on the position of the light spot on the surface of the substrate 4 (imaging plane). A vacuum chamber 12 includes the electron optical system 13, the stage 5, the interferometer 8, the mark detection unit 9, and the focus detection unit 11. The inside of the vacuum chamber 12 is exhausted by a vacuum pump (not illustrated) to be a vacuum environment.

The main control unit 20 is connected with the optical system control unit 21, the mark detection unit control unit 22, the stage control unit 23, the interferometer control unit 24, and a memory 25 (a storage unit or a storage medium). The main control unit 20 can execute a program stored in the memory 25 via a central processing unit (CPU) included therein. The main control unit 20 controls the control units 21 to 24 by executing the program. Further, based on pattern data (data representing a pattern to be formed) and recipe data stored in the memory 25, the main control unit 20 controls the control units 21 to 24 to perform patterning on the substrate 4. Further, the main control unit 20 can store the above-described various measurement values in the memory 25, and perform processing (processing for alignment control or focus control) based on the measurement values. In addition, the main control unit 20 collaborates with an overlay inspection apparatus 50 (described below). The configurations of the main control unit 20 and the control units 21 to 24 are not limited thereto. These control units can be configured in diverse ways, for example, be configured as a single or a plurality of control units (for example, processing unit(s) including a CPU). These control units are generally referred to as a control unit 200.

The overlay inspection apparatus 50 inspects (measures) overlay inspection marks 15 on the substrate 4. The overlay inspection mark detection unit 14 in the overlay inspection apparatus 50 detects overlay inspection marks 15 formed on the substrate 4. An overlay inspection apparatus control unit 26 processes signals (image signals) of images of overlay inspection marks 15 acquired by the overlay inspection mark detection unit 14 to acquire (measure) overlay deviations (overlay errors). The overlay inspection apparatus 50 and the overlay inspection apparatus control unit 26 may be disposed outside the lithography apparatus 1 and connected with the lithography apparatus 1 for communication, or may be disposed inside the lithography apparatus 1. In the former case, the control unit 200 can receive and acquire information about a first overlay inspection and a second overlay inspection (described below) from the overlay inspection apparatus 50. Although the electron optical system 13 irradiates the substrate 4 with one electron beam as illustrated in FIG. 1, it may irradiate the substrate 4 with a plurality of electron beams. The latter case is more advantageous in terms of the throughput of the lithography apparatus 1 than the former case.

### [Patterning Strategy]

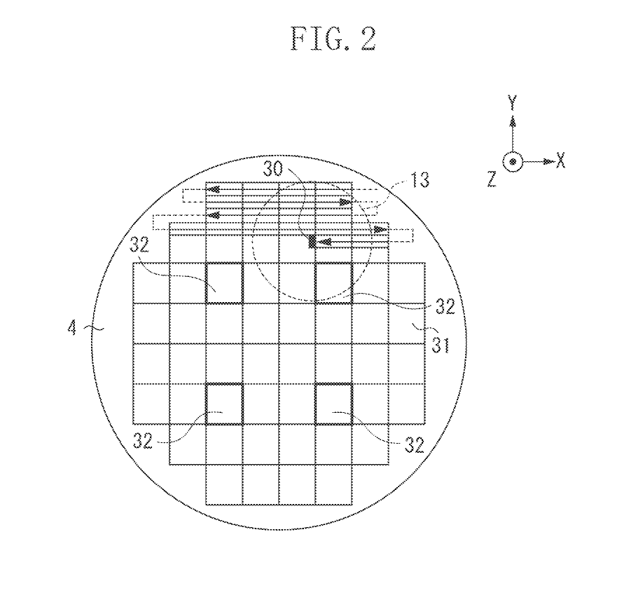

FIG. 2 illustrates an example of a patterning strategy in the lithography apparatus 1. FIG. 2 illustrates a case where one electron optical system 13 irradiates the substrate 4 with an electron beam. A rectangle light receiving area 30 at the central portion of the electron optical system 13 may be individually and selectively irradiated with a plurality of electron beams. The width of the light receiving area 30 can be, for example, 50 to 100 μm in the Y-axis direction. For example, the control unit 200 repeats scanning (movement) of the substrate 4 (stage 5) in the X-axis direction and step movement of the substrate 4 (stage 5) in the Y-axis direction for each scan to achieve patterning (drawing) on the substrate 4.

Referring to FIG. 2, solid line arrows indicate the progress of scanning in the light receiving area 30 on the substrate 4, and dashed lines indicate the step movement of the substrate 4 performed while performing electron beam blanking. The control unit 200 can repeat such scanning and step movement to perform electron beam blanking based on pattern data and electron beam deflection by the deflector 3b, thus achieving patterning on the substrate 4 advantageously in terms of positional accuracy or overlay accuracy.

### [Processing Flow]

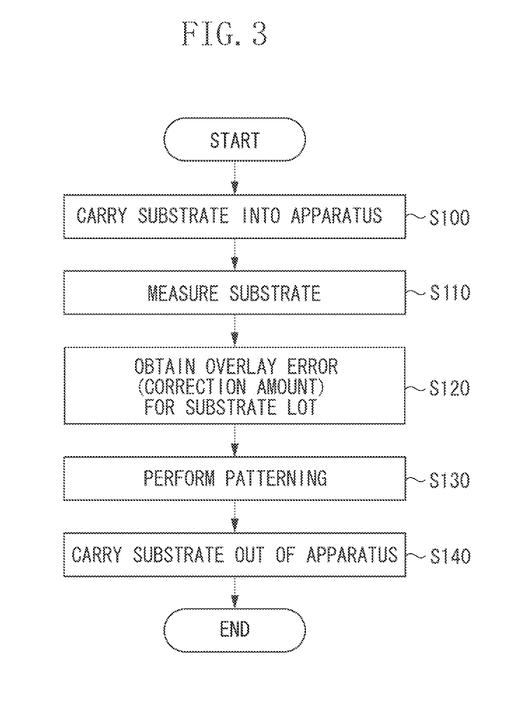

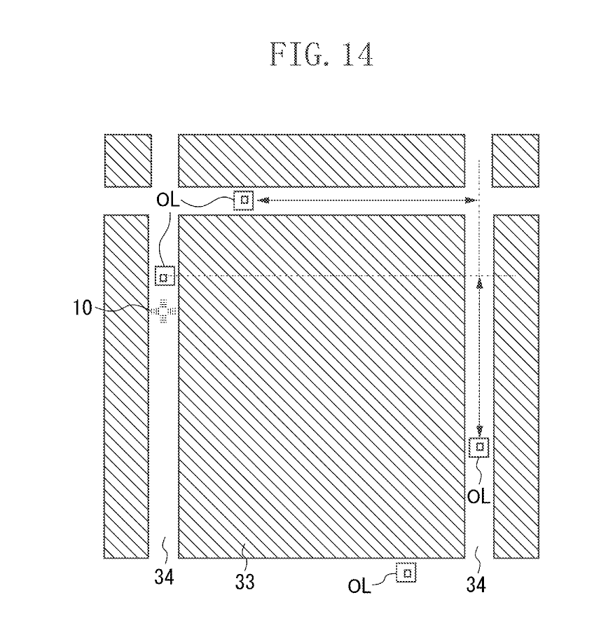

FIG. 3 is a flowchart illustrating common processing according to the first to the third exemplary embodiments. In FIG. 3, when this processing is started, in step S100, the control unit 200 carries a substrate into the lithography apparatus 1. In step S110, the control unit 200 measures the substrate. More specifically, the control unit 200 performs alignment measurement and focus measurement on the relevant substrate. First of all, the alignment measurement will be described below. Referring to FIG. 2, an alignment mark 10 (refer to FIG. 14) is formed in a scribing area 34 around each shot area 31. For example, via the mark detection unit 9, the control unit 200 detects the alignment mark 10 formed for each of a plurality of sample shot areas 32 set through user's selection. The control unit 200 acquires the position of the alignment mark 10 related to each sample shot area based on outputs of the mark detection unit 9. Then, based on the positions of a plurality of the alignment marks 10, the control unit 200 acquires the positions of all shot areas already formed on the substrate 4 (acquires a regression formula representing the positions). Thus, the control unit 200 can perform patterning on the current layer by overlaying a pattern onto the pattern of the preceding layer. In addition, based on the alignment measurement similar to that in the relevant patterning, the control unit 200 can form various marks for overlay inspection (described below). The sample shot areas 32 may desirably be selected in consideration of a measurement error, measurement accuracy, and throughput. FIG. 2 illustrates an example of desirable selection of sample shot areas 32.

When the mark detection unit 9 captures an image of a stationary alignment mark, the alignment mark 10 as illustrated in FIG. 14 is suitable. Positions of the alignment marks 10 in the X- and Y-axis directions can be measured.

The control unit 200 acquires the position of each shot area (a regression formula representing the relevant position) based on the position of the stage 5 measured via the interferometer 8 and the amount of deviation from the design position of the alignment mark 10 relating to each sample shot area 32. To acquire coefficients of the regression formula, for example, the minimum square method is used. For example, position coordinates (x′, y′) of each shot area 31 on the substrate are represented by Regression Formula (1) by using position coordinates (x, y) of each design shot area 31. The control unit 200 controls operations of the stage 5 and the electron optical system 13 to perform patterning (drawing) in the shot area having position coordinates (x′, y′) acquired by Formula (1). In Formula (1), Sₓ and S_{y} denote coefficients representing the translational displacement, mₓ and m_{y} denote coefficients relating to the magnification, and cos θx, −sin θy, sin θx, and cos θy denote coefficients relating to the rotation of the coordinate axes.

$$( \begin{matrix}{x}^{′} \\ {y}^{′}\end{matrix} ) = ( \begin{matrix}{S}_{x} \\ {S}_{y}\end{matrix} ) + ( \begin{matrix}{m}_{x} cos θ x & - {m}_{y} sin θ y \\ {m}_{x} sin θ x & {m}_{y} cos θ y\end{matrix} ) ( \begin{matrix}x \\ y\end{matrix} ) \qquad ( 1 )$$

In focus measurement, the control unit 200 measures the positions (heights) of a plurality of portions in the Z-axis direction on the surface of the substrate 4 based on, for example, outputs of the focus detection unit 11 including an optical sensor or an capacitance sensor as described above.

In step S120, the control unit 200 acquires information about overlay errors in the processing target substrate lot (or information for compensating the errors) from the memory 25. The method for generating the information will be described below.

In step S130, the control unit 200 performs patterning based on the information acquired in step S120. In the patterning, the control unit 200 controls the operation of the stage 5 so that the positions on the surface of the substrate 4 fall within the electron beam focal depth based on the above-described focus measurement. Finally, in step S140, the control unit 200 carries out the substrate 4, on which the patterning has been performed, out of the lithography apparatus 1.

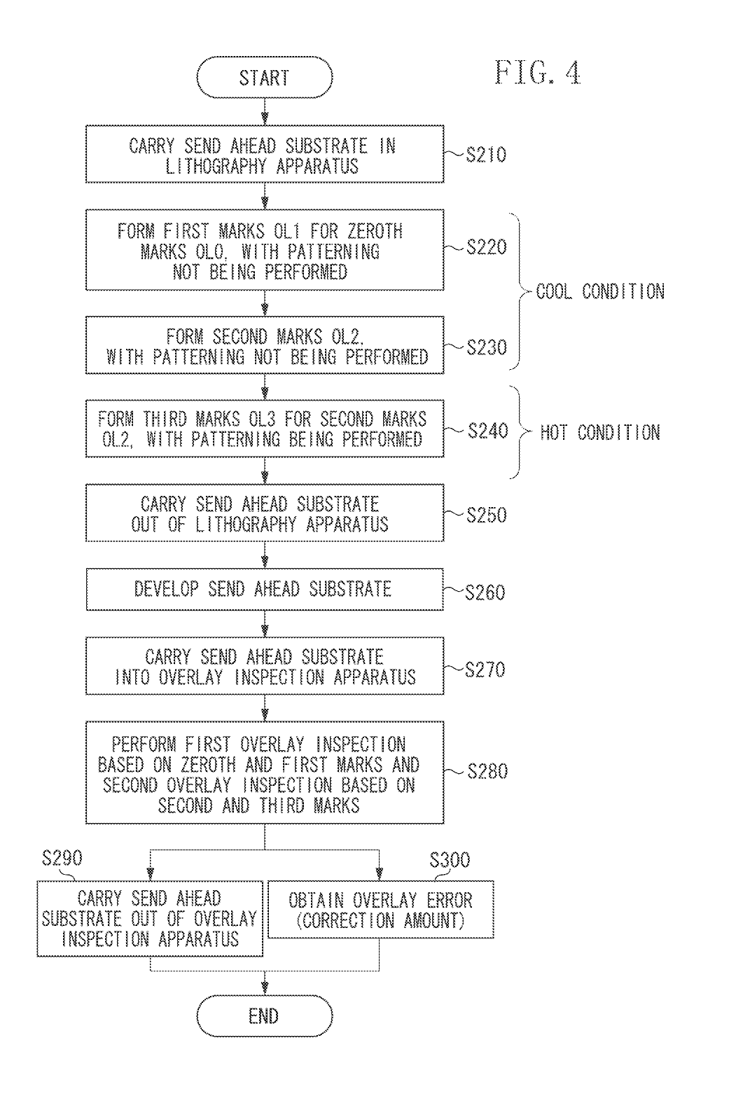

A method for generating information relating to overlay errors (step S120 illustrated in FIG. 3) will be described in detail below with reference to FIG. 4. FIG. 4 is a flowchart illustrating the processing in step S120 illustrated in FIG. 3. This processing will be described below with reference to FIG. 4. In FIG. 4, when this processing is started, in step S210, the control unit 200 carries a send ahead substrate (also referred to as send ahead wafer or a first substrate for condition setting) relating to a target lot in the lithography apparatus 1. In step S220 (first process), for a zeroth marks OL0 for overlay inspection already formed on the send ahead substrate, the control unit 200 forms (draws) a first mark OL1 for overlay inspection to be paired with a zeroth mark OL0, not accompanied by patterning. In step S230 (first process), for a pair of the zeroth mark OL0 and the first mark OL1, the control unit 200 forms (draws) a second mark OL2 for overlay inspection at a position adjacent to the zeroth mark OL0 and at positions at intervals of a distance L1 (shorter than a distance L0 between the zeroth marks OL0) from the adjacent position, not accompanied by the patterning. The control unit 200 forms a plurality of the second marks OL2 at intervals of the distance L1 in this way. The control unit 200 may perform the processing in step S220 and the processing in step S230 alternately in a single step. In step S240 (second process), for each of the second marks OL2, the control unit 200 forms (draws) a third mark OL3 for overlay inspection to be paired with the corresponding second mark OL2, accompanied by patterning. The control unit 200 forms a plurality of third marks OL3 at intervals of the distance L1 in this way. In step S250, the control unit 200 carries the send ahead substrate out of the lithography apparatus 1. In step S260, the control unit 200 develops the send ahead substrate. However, for example, when the control unit 200 performs an overlay inspection within the lithography apparatus 1 by using a latent image, the relevant carry-out and developing processes are not essential and can be omitted. In step S270, the control unit 200 carries the send ahead substrate in the overlay inspection apparatus 50 (or in an overlay inspection unit in the lithography apparatus 1). In step S280, the control unit 200 performs a first overlay inspection based on the zeroth mark OL0 and the first mark OL1, and a second overlay inspection based on the second marks OL2 and the third marks OL3. In step S290, the control unit 200 carries the send ahead substrate out of the overlay inspection apparatus (unit) 50. In parallel to the carry-out process, in step S300, the control unit 200 acquires the correction amount for control of at least one of the electron optical system 13 and the stage 5 for compensating overlay errors, based on the first and the second inspections in step S280. For example, the correction amount may be related to at least one of measurement values and target values of the control amount for the relevant control. The control amount related to the electron optical system 13 may be, for example, the amount (displacement amount on the substrate) of electron beam deflection by the deflector 3b. Further, the control amount relating to the stage 5 may be, for example, the position of the stage 5. The correction amount is stored in the memory 25.

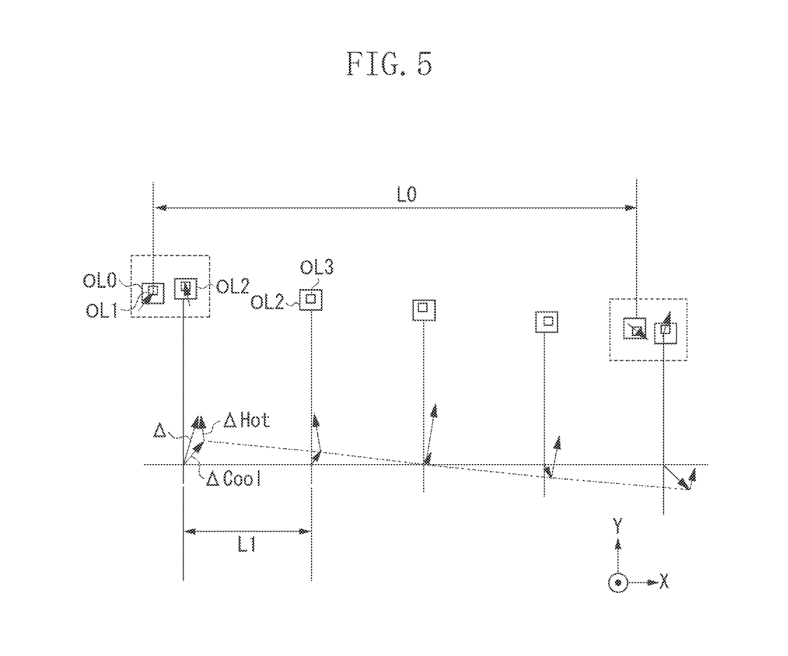

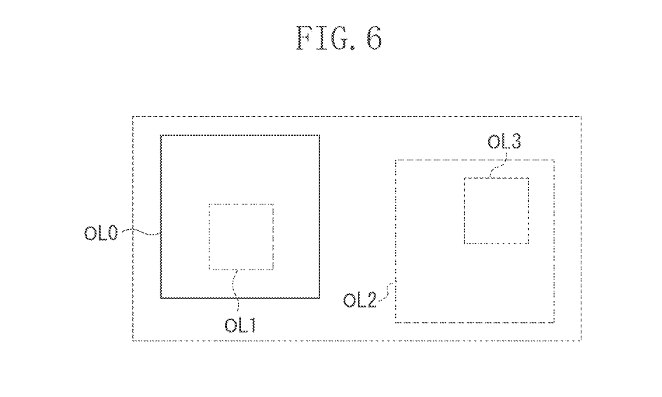

A method of patterning (drawing) performed in steps S220 to S240 and a method of correction amount acquisition performed in step S300 will be further described below with reference to FIGS. 5 and 6.

FIG. 5 illustrates an algorithm for acquiring overlay errors (correction amounts). Referring to FIG. 5, on the send ahead substrate, a pattern has been formed on the preceding layer and the zeroth marks (OL0) have been formed at intervals of the distance L0. In step S220, the control unit 200 forms first marks OL1 corresponding to zeroth marks OL0. In step S230, the control unit 200 forms the second mark OL2 adjacent to the zeroth mark OL0 at the distance L1 that is shorter than the distance L0 between the zeroth marks OL0. The distance L1 is not necessarily an equal distance and may be changed, for example, decreased in areas where high overlay accuracy is required. FIG. 6 illustrates an example of a configuration of overlay inspection marks. The overlay inspection measures, for example, the difference (deviation) between the position of a box-shaped inner mark and the position of a box-shaped outer mark. FIG. 6 illustrates an example in which the zeroth mark OL0 is formed as an outer mark and the first mark OL1 is formed as an inner mark. In steps S220 and S230, since the control unit 200 forms first mark OL1 and second mark OL2, not accompanied by patterning, heating (thermal deformation) of the send ahead substrate can be considered to be ignorable. This state is referred to as a non-heating state. Referring to FIG. 5, ΔCool indicates the positional difference (deviation) of the first mark OL1 from the zeroth mark OL0 in the non-heating state, measured by the overlay inspection apparatus 50. Although ΔCool does not include the influence due to the thermal distortion of the substrate, it includes the influence due to other factors (for example, a magnetic field, charging, and an error specific to the unit of the lithography apparatus 1). In step S240, the control unit 200 forms the third mark OL3 accompanied by patterning. Therefore, heating (thermal deformation) on the send ahead substrate is not ignorable. This state is referred to as a heating state. Referring to FIG. 5, ΔHot indicates the positional difference (deviation) of the third mark OL3 from the second mark OL2 in the heating state, measured by the overlay inspection apparatus 50.

ΔHot can include not only an overlay error due to thermal distortion of the substrate but also an overlay error due to the substrate charged by electron irradiation. Since the second mark OL2 is formed at a position adjacent to the zeroth mark OL0, the overlay error ΔCool can be considered to have arisen at a position where the overlay error ΔHot was acquired. Therefore, an overlay error (correction amount) Δ at intervals of the distance between the second marks OL2 (shorter than the distance between the zeroth marks OL0) can be acquired by adding the above-described two overlay errors, i.e., based on the following Formula (2).

Δ=ΔCool+ΔHot (2)

The zeroth marks OL0 are not formed at intervals of the distance L1, different from the first marks OL1.

Therefore, in the present exemplary embodiment, the control unit 200 acquires overlay errors at intervals of the distance L1 in the non-heating state, on a presumptive basis. For example, with a small magnetic field change over the distance between the zeroth marks OL0, linear approximation (alignment interpolation) can be performed on the relevant overlay error. Thus, overlay errors in the non-heating state and the heating state can be acquired at intervals of the distance L1 shorter than the distance L0 between the zeroth marks OL0. Therefore, with Formula (2), the overlay error Δ (correction amount) after performing patterning can be acquired at intervals of the distance L1.

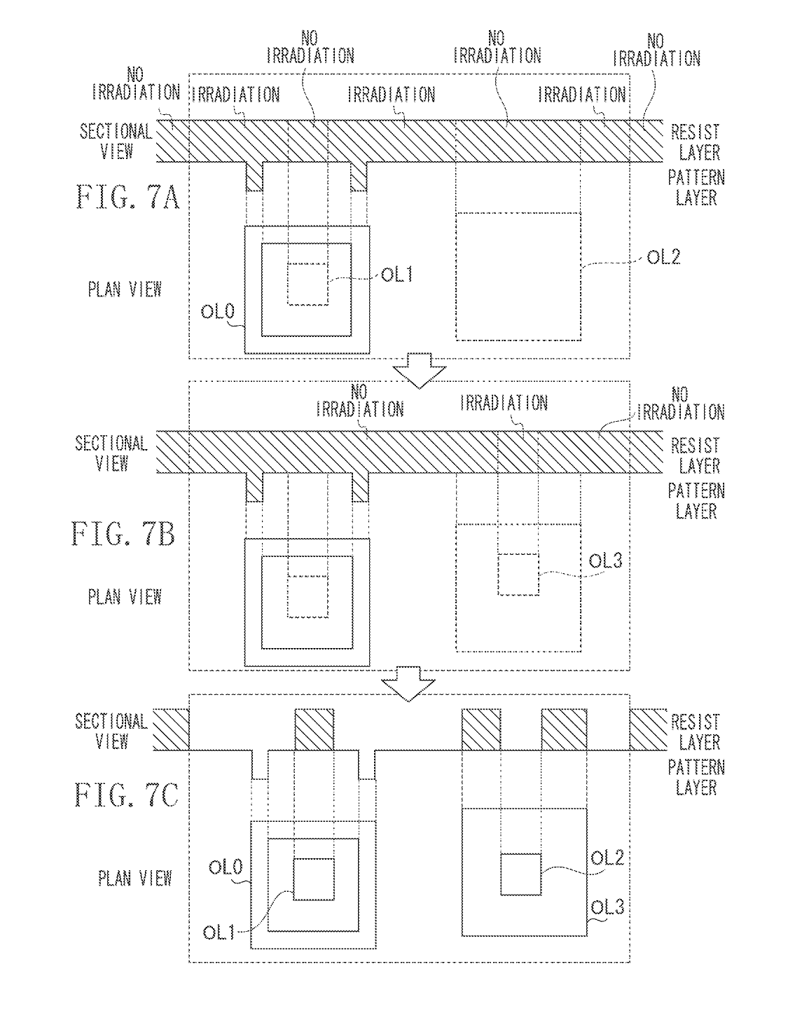

FIGS. 7A, 7B, and 7C illustrate examples of configurations of the overlay inspection marks. Example cases where a positive resist is used will be described below. FIG. 7A illustrates a sectional view and a plan view of a pattern that can be acquired through (latent image) patterning in the non-heating state. FIG. 7B illustrates a sectional view and a plan view of a pattern that can be acquired through (latent image) patterning in the heating state. FIG. 7C illustrates a sectional view and a plan view of a pattern that can be acquired through development. Referring to FIG. 7A, a resist layer is stacked on a pattern layer on which the zeroth mark OL0 is formed. In the patterning in the non-heating state illustrated in FIG. 7A, the control unit 200 irradiates the outside of the first mark OL1 (box-shaped inner mark) and the second mark OL2 (box-shaped outer mark) with an electron beam. In the patterning in the heating state illustrated in FIG. 7B, the control unit 200 irradiates the inside of the third mark OL3 (box-shaped inner mark) in parallel with patterning with an electron beam. FIG. 7C illustrates a resist pattern acquired by developing the (latent image) patterns (i.e., dissolving resist in areas irradiated with an electron beam) described with reference to FIGS. 7A and 7B. The control unit 200 performs an overlay inspection as described in step S280 on the thus-formed resist pattern. The marks for the overlay inspection are not limited to box-shaped marks, and may be marks having other shapes (e.g., line marks, and line and space marks). The shape of marks advantageous in terms of measurement accuracy should be selected in consideration of the influence of processing (e.g., resist developing process) on the substrate and the overlay inspection method. After completing the overlay inspection, by removing the resist from the send ahead substrate, the substrate becomes reusable. The above-described processing enables efficiently acquiring overlay errors (correction amounts) by using less number of substrates, and enables using the send ahead substrate for article manufacturing. Therefore, the substrate subjected to the processing (patterning) in the flowchart illustrated in FIG. 3 may be at least one of the send ahead substrate (first substrate for condition setting) and a substrate (second substrate) different from the send ahead substrate.

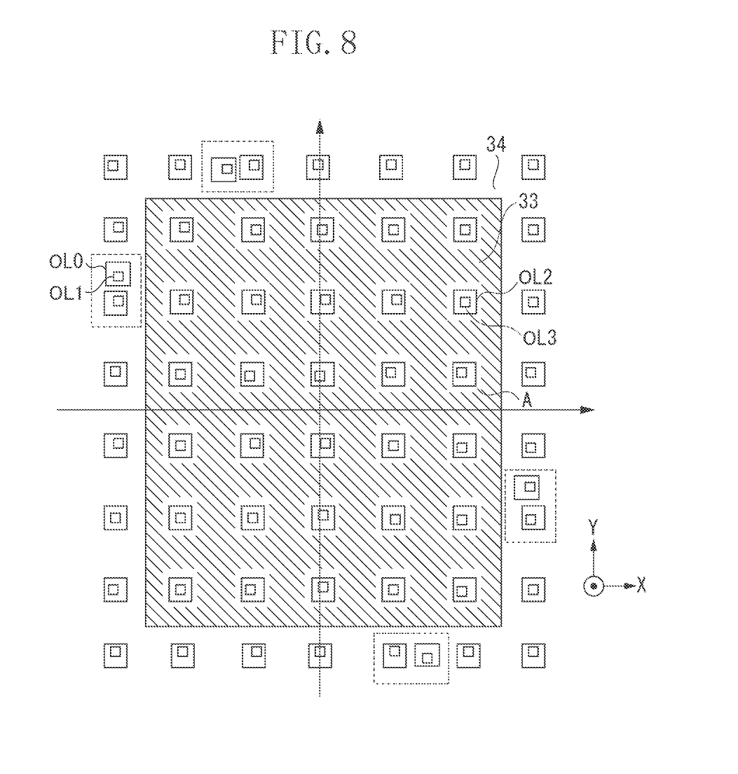

Areas (arrangements of OL2 and OL3) for forming second marks OL2 and third marks OL3 for overlay inspection can be changed or set by the control unit 200, and are not limited to the inside of the scribing area 34. FIG. 8 illustrates an example of an arrangement of overlay inspection marks. As illustrated in FIG. 8, the second marks OL2 and the third marks OL3 for overlay inspection may be two-dimensionally laid out (arranged) at intervals of a distance shorter than the distance between the zeroth marks OL0 in the area 33 in which patterning should be performed. In this case, an area A around overlay inspection marks is an area in which patterning is not to be performed. When the lithography apparatus 1 is an electron beam drawing apparatus, changing drawing data enables drawing marks (marks OL2 and OL3) for overlay inspection at intervals of a desired distance in the area (e.g., a 26 mm×33 mm shot area). Then, after overlay error (correction amounts) is acquired and then resist is removed as described above, the send ahead substrate becomes reusable for article manufacturing (article production). Further, with a pattern relating to an article (e.g., a semiconductor device) that has been formed in the area 33, the line width (e.g., about 10 to 20 nm) is small enough compared with the line width of inspection marks (e.g., about 1 μm). Therefore, the influence of a pattern for the article on overlay inspection (measurement accuracy) is very small and therefore is ignorable.

As clearly understood from the above descriptions, according to the present exemplary embodiment, it is possible to provide a lithography apparatus that is advantageous in terms of overlay performance (overlay accuracy).

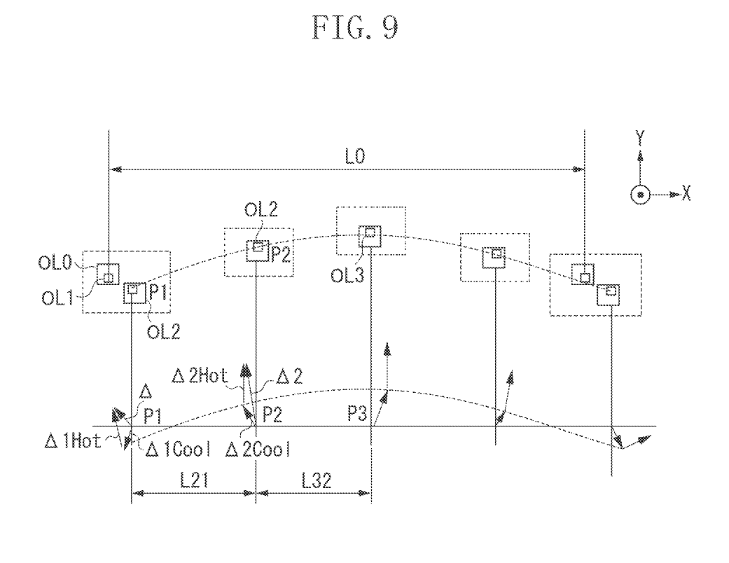

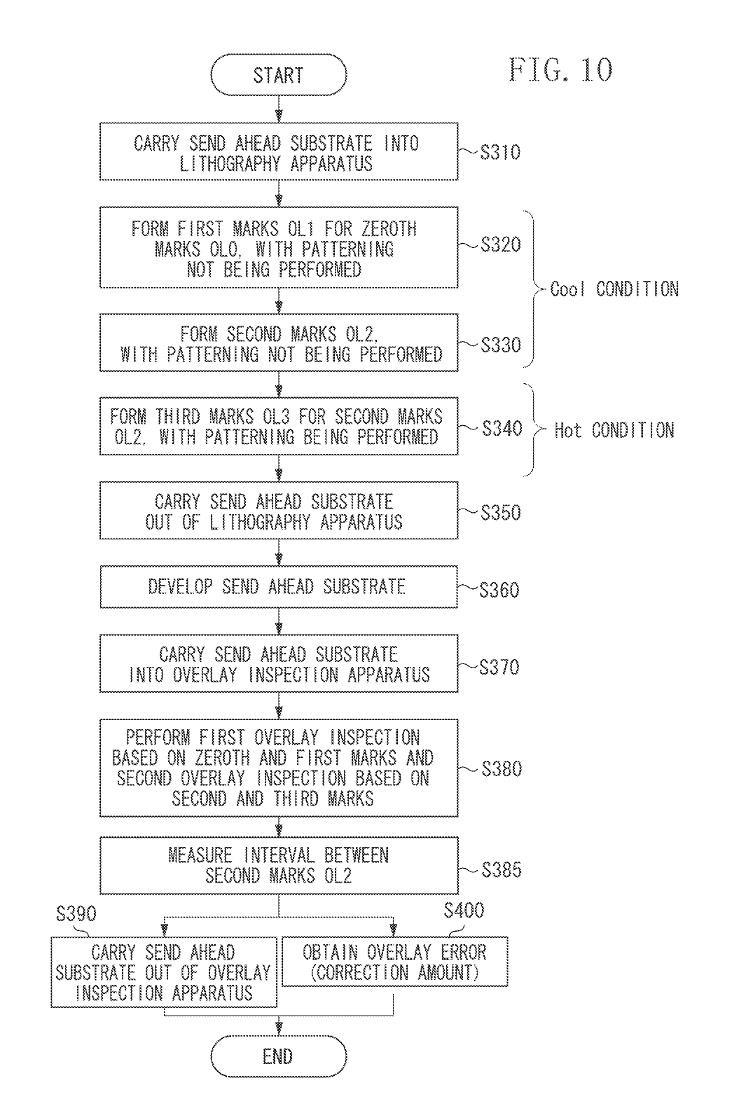

In the first exemplary embodiment, linear approximation can be performed on (changes of) overlay errors in the non-heating state over intervals of the distance between the zeroth marks OL0. On the other hand, a second exemplary embodiment differs from the first exemplary embodiment in the method for acquiring (interpolating) overlay errors in the non-heating state at intervals of a distance (spatial resolution) shorter than the distance between the zeroth marks OL0. FIG. 9 illustrates an algorithm for acquiring overlay errors according to the second exemplary embodiment. FIG. 10 is a flowchart illustrating processing according to the second exemplary embodiment to be performed in step S120 illustrated in FIG. 3. The second exemplary embodiment will be described below with reference to FIGS. 9 and 10.

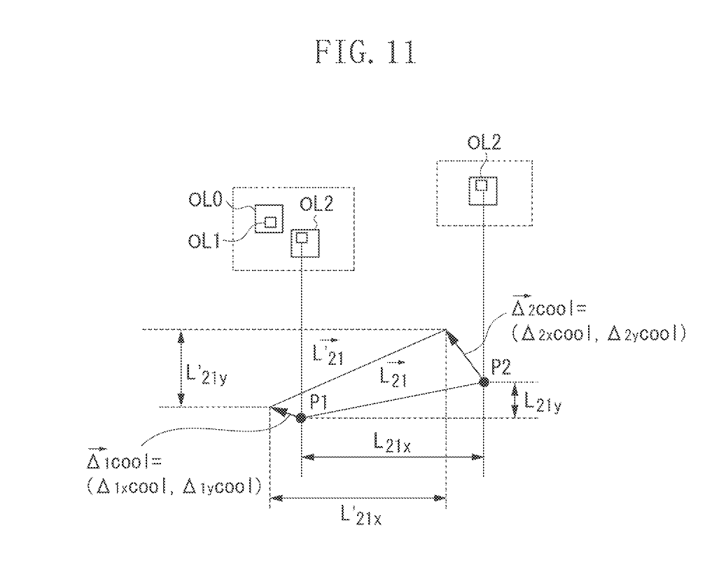

In the flowchart illustrated in FIG. 10, processing to be performed in steps S310 to S380, S390, and S400 is similar to the processing performed in steps S210 to S280, S290, and S300 in the flowchart illustrated in FIG. 4, respectively, and descriptions thereof will be omitted. In step S385, the control unit 200 measures positional differences between a plurality of the second marks OL2 formed on the send ahead substrate in the non-heating state. The positional differences can be measured by the overlay inspection apparatus 50. FIG. 11 complements the descriptions of FIG. 9. Referring to FIG. 9, a position P1 indicates the position of a second mark OL2 formed adjacent to the zeroth mark (OL0), and a position P2 indicates the position of a second mark OL2 adjacent to the second mark OL2 at the position P1. Referring to FIG. 11, a relation between positional differences (measurement values) between adjacent second marks OL2 at positions P1 and P2 and overlay errors in the non-heating state is represented by the following Formula (3).

\vec{L}₂₁′=\vec{L}₂₁+\vec{Δ}₁cool+\vec{Δ}₂cool (3)

Relations between the X and Y components are represented by the following Formula (4).

$$\{ \begin{matrix}{L}_{21 x}^{′} = {L}_{21 x} + {Δ}_{1 x} cool + {Δ}_{2 x} cool \\ {L}_{21 y}^{′} = {L}_{21 y} + {Δ}_{1 y} cool + {Δ}_{2 y} cool\end{matrix} \qquad ( 4 )$$

where L₂₁=(L₂₁ₓ, L_{21y}) denotes a design value of a positional difference between the two adjacent second marks OL2. L₂₁′=(L′₂₁ₓ, L′_{21y}) denotes a measurement value of a positional difference between the two adjacent second marks OL2. Δ₁cool=(Δ₁ₓcool, Δ_{1y}cool) denotes an overlay error at the position P1 in the non-heating state. Δ₂cool=(Δ₂ₓcool, Δ_{2y}cool) denotes an overlay error at the position P2 in the non-heating state.

Referring to FIG. 11, Δ₁cool=(Δ₁ₓcool, Δ_{1y}cool) can be regarded as a positional difference (overlay error) between the zeroth mark OL0 and the first mark OL1. Therefore, Δ₂cool=(Δ₂ₓcool, Δ_{2y}cool) can be calculated by Formula (4). Similar to Formula (4), a relation between positional differences (measurement values) between adjacent second marks OL2 at positions P2 and P3 and overlay errors in the non-heating state is represented by the following Formula (5).

$$\{ \begin{matrix}{L}_{32 x}^{′} = {L}_{32 x} + {Δ}_{2 x} cool + {Δ}_{3 x} cool \\ {L}_{32 y}^{′} = {L}_{32 y} + {Δ}_{2 y} cool + {Δ}_{3 y} cool\end{matrix} \qquad ( 5 )$$

Since Δ₂cool=(Δ₂ₓcool, Δ_{2y}cool) has already been acquired, an overlay error in the non-heating state at the position P3, Δ₃cool=(Δ₃ₓcool, Δ_{3y}cool), can be calculated by Formula (5).

Thus, overlay errors in the non-heating state can be sequentially acquired with a spatial resolution smaller than the distance between the zeroth marks L0. Therefore, according to the present exemplary embodiment, it is possible to provide a lithography apparatus that is more advantageous in terms of overlay performance (overlay accuracy).

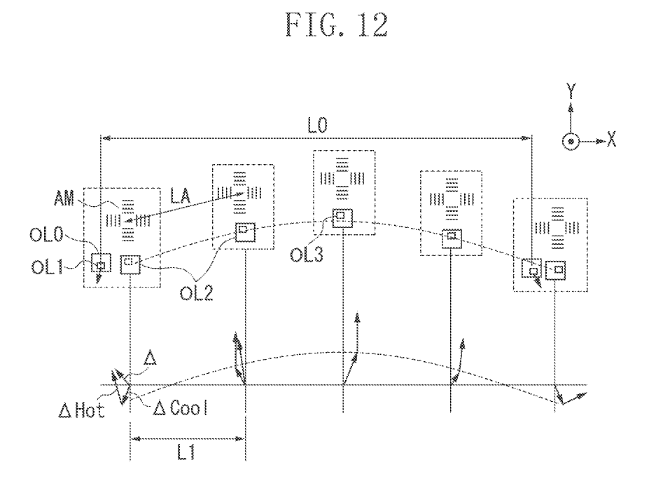

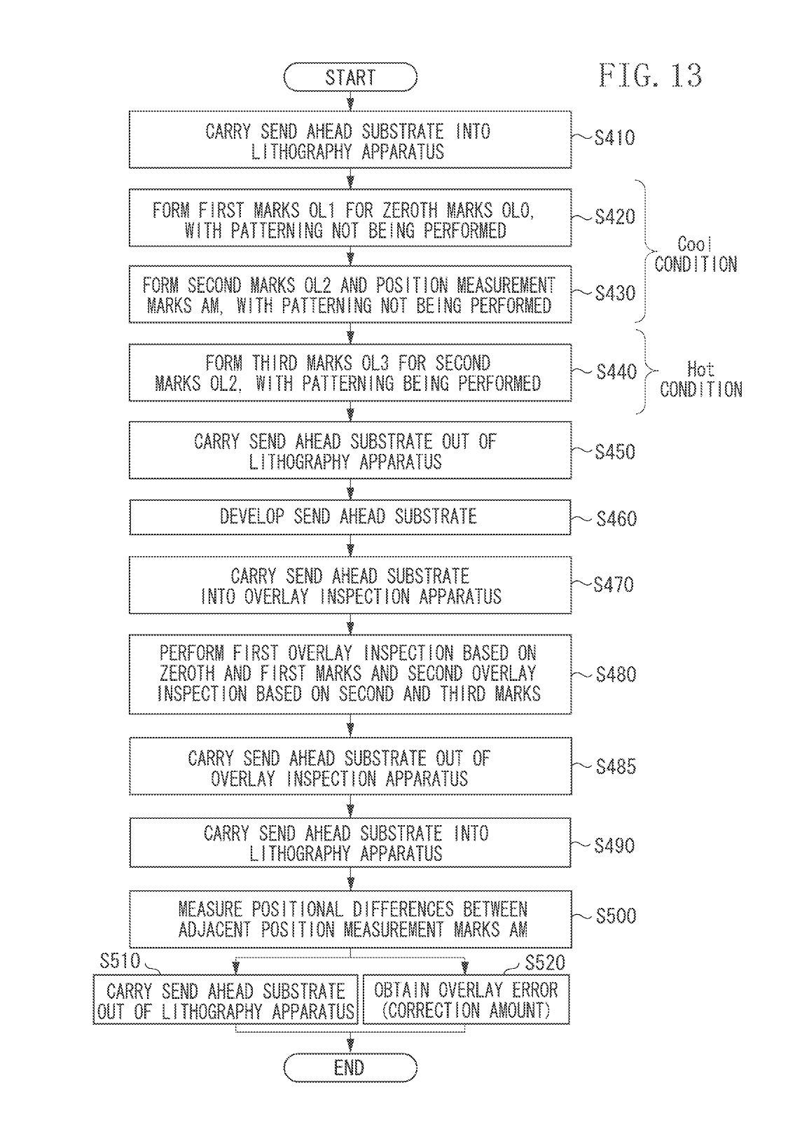

A third exemplary embodiment differs from the second exemplary embodiment in that position measurement marks (fourth marks), which are more advantageous than overlay inspection marks in terms of position measurement accuracy, are formed (drawn) in the non-heating state and that overlay errors in the non-heating state are acquired through interpolation by using the distance between the position measurement marks. FIG. 12 illustrates an algorithm for acquiring overlay errors in the third exemplary embodiment. FIG. 13 is a flowchart illustrating processing according to the third exemplary embodiment to be performed in step S120 illustrated in FIG. 3. The third exemplary embodiment will be described below with reference to FIGS. 12 and 13.

In the flowchart illustrated in FIG. 13, processing to be performed in steps S410, S420, and S440 to S480 is similar to the processing performed in steps S210, S220, and S240 to S280 in the flowchart illustrated in FIG. 4, respectively, and descriptions thereof will be omitted. In step S430, the control unit 200 forms (draws) a second mark OL2 and a position measurement mark AM at a position adjacent to a zeroth mark OL0 and at positions at intervals of a distance L1 (shorter than the distance L0) from the adjacent position, not accompanied by patterning. Step S430 is a part of the first process similar to step S230 illustrated in FIG. 4. In step S485, the control unit 200 carries the send ahead substrate out of the overlay inspection apparatus 50. In step S490, the control unit 200 carries the send ahead substrate in the lithography apparatus 1. In step S500, the control unit 200 measures positional differences LA between adjacent position measurement marks AM by using the mark detection unit 9. Position measurement marks AM include a larger number of mark elements than second marks OL2 used in step S385 according to the second exemplary embodiment, and therefore are more advantageous in terms of measurement accuracy than the second marks OL2 (this means that position measurement with higher accuracy can be expected). In step S510, the control unit 200 carries the send ahead substrate out of the lithography apparatus 1. In parallel to the carry-out process, in step S520, the control unit 200 acquires correction amounts for control for compensating overlay errors based on the first and the second overlay inspections in step S480 and positional differences between adjacent position measurement marks in step S500. The correction amount may be related to control of at least either one of the electron optical system 13 and the stage 5. The correction amount is stored in the memory 25. Thus, in the third exemplary embodiment, using position measurement marks AM (fourth marks) enables acquiring overlay errors in the non-heating state with higher accuracy than in the second exemplary embodiment. Therefore, according to the present exemplary embodiment, it is possible to provide a lithography apparatus that is more advantageous in terms of overlay performance (overlay accuracy).

### [Exemplary Embodiments for Article Manufacturing Method]

The article manufacturing (production) method according to the exemplary embodiments of the present disclosure is suitable, for example, for manufacturing articles including micro and nano devices such as semiconductor devices, and elements having a fine structure. The article manufacturing method according to an exemplary embodiment can include a process of performing patterning on a substrate, and a process of processing (developing) the substrate, on which the patterning has been performed, in the patterning process, by using the above-described lithography apparatus. The manufacturing method can further include other known processes (oxidization, coating, vapor deposition, doping, flatting, etching, resist removing, dicing, bonding, and packaging). The article manufacturing method according to the present exemplary embodiment is advantageous compared to the conventional method in term of at least one of performance, quality, productivity, and manufacturing cost of articles.

While the present disclosure has specifically been described based on the above-described preferred exemplary embodiments, the present disclosure is not limited thereto and embodiments of the present disclosure can be modified in diverse ways within the gist of the present disclosure.

For example, in the above descriptions, the blanking unit (blanker array) includes an array of electrode pairs that can be individually driven, the configuration is not limited thereto. The blanking unit may only be required to be an array of elements having a blanking function. For example, the blanking unit can include a reflective electron patterning device as discussed in U.S. Pat. No. 7,816,655. The device includes a pattern on the top surface, an electron reflective portion in the pattern, and an electron non-reflective portion in the pattern. The device further includes a circuit array for dynamically changing the electron reflective portion and the electron non-reflective portion in the relevant pattern, by using a plurality of pixels that can be independently controlled. Thus, the blanking unit may be an array of elements (blankers) for performing charged-particle beam blanking by changing reflective portions for a charged-particle beam to non-reflective portions. It is natural that the configuration of a charged-particle optical system having such reflective devices and the configuration of a charged-particle optical system having transmissive devices such as an array of electrode pairs are different from each other.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2014-222045, filed Oct. 30, 2014, which is hereby incorporated by reference herein in its entirety.

What is claimed is:

1. A lithography apparatus for performing patterning on a substrate, the apparatus comprising:
a stage configured to hold the substrate and be movable;
an irradiation device configured to irradiate the substrate with a beam for the patterning; and
a controller configured to cause the stage and the irradiation device to perform a first process of forming, on a substrate including a zeroth mark for overlay inspection, a first mark for overlay inspection to be paired with the zeroth mark and a second mark for overlay inspection, with the patterning not being performed, and to perform a second process of forming, on the substrate, a third mark for overlay inspection to be paired with the second mark, with the patterning being performed.

2. The lithography apparatus according to claim 1, wherein the controller is configured to set an arrangement of the second and the third marks, and to cause the stage and the irradiation device to perform the first and the second processes based on the set arrangement.

3. The lithography apparatus according to claim 1, wherein the first process forms a plurality of the first mark at a first interval, and forms a plurality of the second mark at a second interval shorter than the first interval.

4. The lithography apparatus according to claim 1, wherein the controller is configured to set an arrangement of the second and third marks in a region on the substrate in which the patterning is to be performed.

5. The lithography apparatus according to claim 1, wherein the controller is configured to cause the stage and the irradiation device to perform the patterning based on a first overlay inspection based on the zeroth and first marks formed on the substrate, and a second overlay inspection based on the second and third marks formed on the substrate.

6. The lithography apparatus according to claim 5,
wherein the irradiation device includes a deflector for deflecting the beam to scan the beam on the substrate, and
wherein the controller is configured to control the deflector based on the first and second overlay inspections.

7. The lithography apparatus according to claim 5, further comprising an inspection device configured to perform the first or second overlay inspections or both.

8. The lithography apparatus according to claim 5, wherein the controller is configured to receive information about the first and second overlay inspections from an overlay inspection apparatus.

9. The lithography apparatus according to claim 5,
wherein the first process forms a plurality of the first mark at a first interval, and forms a plurality of the second mark at a second interval shorter than the first interval, and
wherein the controller is configured to interpolate information about the first overlay inspection based on the first interval at which the plurality of the first mark is formed and the second interval at which the plurality of the second mark is formed.

10. The lithography apparatus according to claim 5, wherein the first process forms a plurality of the first mark at a first interval, and forms a plurality of the second mark at a second interval shorter than the first interval, and
wherein the controller is configured to interpolate information about the first overlay inspection based on the second interval.

11. The lithography apparatus according to claim 5,
wherein the first process forms a plurality of the first mark at a first interval, and forms a plurality of the second mark at a second interval shorter than the first interval, and
wherein the controller is configured to cause, in the first process, the stage and the irradiation device to form a fourth mark, which has elements thereof whose number is larger than a number of elements of the second mark, in parallel with forming of the plurality of the second mark, and to interpolate information about the first overlay inspection based on an interval at which a plurality of the fourth mark is formed.

12. A lithography method of performing patterning on a substrate, the method comprising steps of:
performing a first process of forming, on a first substrate including a zeroth mark for overlay inspection, a first mark for overlay inspection to be paired with the zeroth mark and a second mark for overlay inspection, with the patterning not being performed;
performing a second process of forming, on the first substrate, a third mark for overlay inspection to be paired with the second mark, with the patterning being performed; and
performing the patterning on the first substrate or a second substrate different from the first substrate or both based on a first overlay inspection based on the zeroth and first marks formed on the first substrate, and a second overlay inspection based on the second and third marks formed on the first substrate.

13. The lithography method according to claim 12, wherein the second and third marks are formed in a region on the first substrate in which the patterning is to be performed.

14. A method of manufacturing an article, the method comprising steps of:
performing patterning on a substrate using a lithography apparatus; and
processing the substrate, on which the patterning has been performed, to manufacture the article,
wherein the lithography apparatus includes:
a stage configured to hold the substrate and be movable;
an irradiation device configured to irradiate the substrate with a beam for the patterning; and
a controller configured to cause the stage and the irradiation device to perform a first process of forming, on a substrate including a zeroth mark for overlay inspection, a first mark for overlay inspection to be paired with the zeroth mark and a second mark for overlay inspection, with the patterning not being performed, and to perform a second process of forming, on the substrate, a third mark for overlay inspection to be paired with the second mark, with the patterning being performed.
